(19) United States
(12) Patent Application Publication
(10) Pub. No.: US 2025/0357403 A1
(43) Pub. Date: Nov. 20, 2025

(54) SEMICONDUCTOR PACKAGE AND METHOD OF FABRICATING THE SAME

(71) Applicant: Samsung Electronics Co., Ltd., Suwon-si (KR)

(72) Inventors: DUCKGYU KIM, Suwon-si (KR); HYUNG-SUN JANG, Suwon-si (KR)

(21) Appl. No.: 18/950,333

(22) Filed: Nov. 18, 2024

(30) Foreign Application Priority Data
May 17, 2024 (KR) 10-2024-0064768

(51) Int. Cl. H01L 23/00

(52) U.S. Cl. CPC H01L 24/14; H01L 24/06; H01L 2224/06051; H01L 2224/06102; H01L 2224/14051; H01L 2224/14104

(57) ABSTRACT

A semiconductor package may include a semiconductor die, first and second redistribution insulating layers sequentially stacked below the semiconductor die, first redistribution bonding pads disposed on a bottom surface of the second redistribution insulating layer, and first solder bumps bonded to the first redistribution bonding pads. The first solder bumps may cover and contact side surfaces of the first redistribution bonding pads.

### CROSS-REFERENCE TO RELATED APPLICATIONS

This U.S. non-provisional patent application claims priority under 35 U.S.C. § 119 to Korean Patent Application No. 10-2024-0064768, filed on May 17, 2024, in the Korean Intellectual Property Office, the entire contents of which are hereby incorporated by reference.

### BACKGROUND OF THE INVENTION

The present disclosure relates to a semiconductor package and a method of fabricating the same.

A semiconductor package is configured to facilitate the use of an integrated circuit chip as a component in an electronic device. Conventionally, the semiconductor package includes a printed circuit board (PCB) and a semiconductor chip die, which is mounted on the PCB and is electrically connected to the PCB using bonding wires or bumps. With development of the electronic industry, many studies are being conducted to enhance reliability and durability of the semiconductor package.

### SUMMARY

An embodiment of the inventive concept provides a semiconductor package with improved reliability and durability.

An embodiment of the inventive concept provides a method of increasing a production yield in a process of fabricating a semiconductor package.

According to an embodiment of the inventive concept, a semiconductor package may include a semiconductor die, first and second redistribution insulating layers sequentially stacked below the semiconductor die, first redistribution bonding pads disposed on a bottom surface of the second redistribution insulating layer, and first solder bumps bonded to the first redistribution bonding pads. The first solder bumps may cover and contact side surfaces of the first redistribution bonding pads.

According to an embodiment of the inventive concept, the first solder bumps may also cover and contact bottom surfaces of the first redistribution bonding pads and edges of the redistribution bonding pads. The side surfaces and the bottom surfaces of the first redistribution bonding pads may meet at the edges of the first redistribution bonding pads.

According to an embodiment of the inventive concept, a semiconductor package may include a semiconductor die, a chip bonding pad disposed on a bottom surface of the semiconductor die, first and second redistribution insulating layers stacked below the semiconductor die, a first redistribution pattern, which penetrates the first redistribution insulating layer and is connected to the chip bonding pad, a first redistribution bonding pad, which penetrates the second redistribution insulating layer and is connected to the first redistribution pattern, and a first solder bump bonded to the first redistribution bonding pad. A bottom surface of the first solder bump may be flat, and the first solder bump may be in contact with a bottom surface of the second redistribution insulating layer. The first redistribution bonding pad may not overlap the chip bonding pad in a vertical direction. The first redistribution pattern may have a first thickness, and the first redistribution bonding pad may have a second thickness different from the first thickness.

According to an embodiment of the inventive concept, a semiconductor package may include a semiconductor die, first and second redistribution insulating layers sequentially stacked below the semiconductor die, a first redistribution bonding pad and a second redistribution bonding pad disposed below a bottom surface of the second redistribution insulating layer, a first solder bump bonded to the first redistribution bonding pad, and a second solder bump bonded to the second redistribution bonding pad. The first solder bump may have a tapered shape that decreases in width from a height where the first solder bump contacts a side surface of the first redistribution bonding pad and in a downward direction away from the bottom surface of the second redistribution insulating layer. The second solder bump may have a tapered shape that decreases in width from a height where the second solder bump contacts a side surface of the second redistribution bonding pad and in the downward direction. A bottom portion of the first solder bump may have a first horizontal width, and a bottom portion of the second solder bump may have a second horizontal width different from the first horizontal width.

According to an embodiment of the inventive concept, a method of fabricating a semiconductor package may include preparing a device substrate including device regions and a separation region therebetween, the device substrate including redistribution bonding pads on the device regions, placing solder balls on the redistribution bonding pads, respectively, placing a mold frame on the device substrate, the mold frame including trenches, in which the solder balls are inserted, performing a reflow process while pressing the solder balls with the mold frame to form solder bumps bonded to the redistribution bonding pads, wherein the solder bumps have tapered shapes that decrease in width from a height where the solder bumps contact the redistribution bonding pads and in a downward direction away from the redistribution bonding pads, detaching the mold frame, and performing a singulation process to remove the separation region of the device substrate.

According to an embodiment of the inventive concept, after the performing the singulation process, the semiconductor package may comprise: a subset of the redistribution bonding pads; and a subset of the solder bumps. A respective solder bump of the subset of the solder bumps may have a tapered shape that decreases in width in the downward direction away from the redistribution bonding pads. The respective solder bump of the subset of the solder bumps may be bonded to a respective redistribution bonding pad of the subset of the redistribution bonding pads.

According to an embodiment of the inventive concept, after the detaching of the mold frame, the semiconductor package may comprise: a chip bonding pad; first and second redistribution insulating layers; a first redistribution pattern, which penetrates the first redistribution insulating layer and is connected to the chip bonding pad; a subset of the redistribution bonding pads, which penetrate the second redistribution insulating layer and are connected to the first redistribution pattern; and a subset of the solder bumps bonded to the subset of the redistribution bonding pads. A bottom surface of each solder bump of the subset of the solder bumps may be flat, the subset of the solder bumps may be in contact with a bottom surface of the second redistribution insulating layer, the subset of the redistribution bonding pads may not overlap the chip bonding pad in a vertical direction, the first redistribution pattern may have a first thickness, and the subset of the redistribution bonding pads may have a second thickness different from the first thickness.

### BRIEF DESCRIPTION OF THE DRAWINGS

FIG. 1 is a bottom perspective view illustrating a semiconductor package according to an embodiment of the inventive concept.

FIG. 2 is a sectional view taken along a line A-A′ of FIG. 1.

FIGS. 3A to 3E are enlarged sectional views illustrating a portion ‘P1’ of FIG. 1.

FIG. 4A is a sectional view illustrating a semiconductor package according to an embodiment of the inventive concept.

FIG. 4B is a sectional view illustrating a semiconductor package according to an embodiment of the inventive concept.

FIG. 4C is a sectional view illustrating a semiconductor package according to an embodiment of the inventive concept.

FIG. 4D is a sectional view illustrating a semiconductor package according to an embodiment of the inventive concept.

FIG. 4E is a sectional view illustrating a semiconductor package according to an embodiment of the inventive concept.

FIG. 4F is a sectional view illustrating a semiconductor package according to an embodiment of the inventive concept.

FIG. 4G is a sectional view illustrating a semiconductor package according to an embodiment of the inventive concept.

FIGS. 5A to 5G are sectional views sequentially illustrating a process of fabricating the semiconductor package of FIG. 2, according to an embodiment of the inventive concept.

FIGS. 6A to 6C are sectional views sequentially illustrating a process of fabricating the semiconductor package of FIG. 2, according to an embodiment of the inventive concept.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the present specification, depending on the viewing point, bottom and top surface can be interchangeable. The bottom surface or the top surface may be referred to as a first surface and a second surface, respectively, or as a front surface or a rear surface, respectively. Like reference numerals in the drawings denote like elements, and thus their description will be omitted.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

The term “substrate” may denote a base substrate (e.g., an initial semiconductor substrate forming the base of the wafer in the final wafer product, such as a bulk semiconductor substrate (e.g., formed of crystalline silicon), a silicon on insulator (SOI) substrate, etc.), or a stack structure including such a base substrate and layers formed on the substrate.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

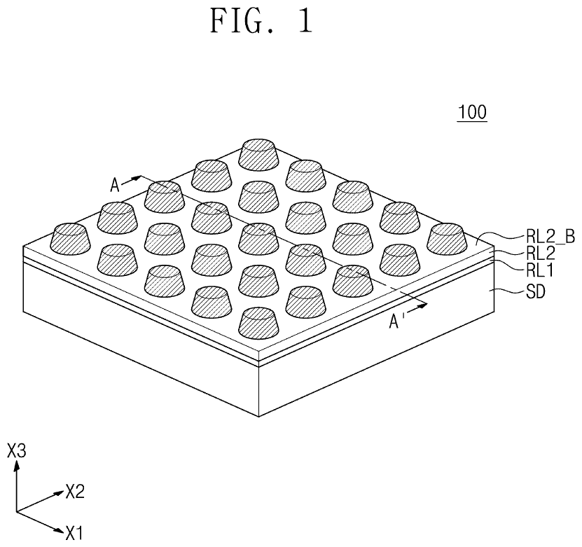

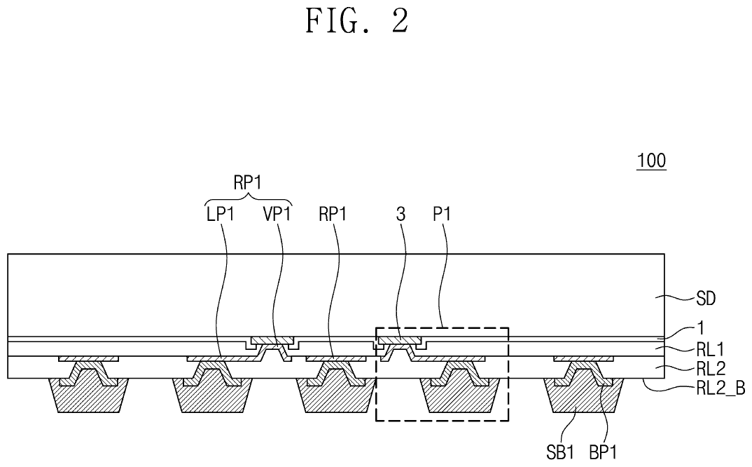

FIG. 1 is a bottom perspective view illustrating a semiconductor package according to an embodiment of the inventive concept. FIG. 2 is a sectional view taken along a line A-A′ of FIG. 1. FIG. 2 illustrates an inverted structure of the semiconductor package of FIG. 1.

Referring to FIGS. 1 and 2, a semiconductor package 100 in the present embodiment may be provided to have a chip-first-type fan-in wafer-level package (FIWLP) structure. The semiconductor package 100 may include a semiconductor die SD. The semiconductor die SD may be referred to as a ‘semiconductor chip’. The semiconductor die SD may be one of image sensor chips, FLASH memory chips, DRAM chips, SRAM chips, EEPROM chips, PRAM chips, MRAM chips, ReRAM chips, or logic chips. The semiconductor die SD may include a semiconductor substrate and transistors, interconnection lines, and interlayer insulating layers, which are provided on the semiconductor substrate.

Chip bonding pads 3 may be disposed on a bottom surface of the semiconductor die SD. The chip bonding pads 3 may be formed of or include at least one metallic material (e.g., copper or aluminum) and/or another conductor. A bottom surface of the semiconductor die SD may be covered with a chip protection layer 1. The chip protection layer 1 may be provided to expose the chip bonding pads 3. In an embodiment, the chip protection layer 1 may include at least one of SiN, SiCN, SiO₂, and polyimide layers.

First and second redistribution insulating layers RL1 and RL2 may be sequentially stacked below a bottom surface of the chip protection layer 1. The first and second redistribution insulating layers RL1 and RL2 may be formed of a photoimageable dielectric (PID) layer. First redistribution patterns RP1 may be disposed between the first and second redistribution insulating layers RL1 and RL2. At least one of the first redistribution patterns RP1 may include a first via portion VP1 and a first line portion LP1. The first via portion VP1 may penetrate the first redistribution insulating layer RL1 and may be in contact with the chip bonding pad 3. The first line portion LP1 may be interposed between the first and second redistribution insulating layers RL1 and RL2. Each of the first redistribution patterns RP1 may be formed of or include at least one metallic material (e.g., copper) and/or another conductor.

FIG. 2 illustrates an example, in which two redistribution insulating layers RL1 and RL2 are provided, but the inventive concept is not limited to this example; for example, three or more redistribution insulating layers may be stacked on the bottom surface of the semiconductor die SD. The second redistribution insulating layer RL2 may correspond to the lowermost one of the redistribution insulating layers. Similarly, although FIG. 2 illustrates an example, in which the first redistribution patterns RP1 are provided to form a single layer, the inventive concept is not limited to this example; for example, the first redistribution patterns RP1 may be provided to form two or more layers.

First redistribution bonding pads BP1 may be disposed below the second redistribution insulating layer RL2. The first redistribution bonding pads BP1 may penetrate the second redistribution insulating layer RL2 and may be in contact with some of the first redistribution patterns RP1. Each of the first redistribution bonding pads BP1 may be formed of or include at least one metallic material (e.g., copper) and/or another conductor. In an embodiment, the first redistribution bonding pad BP1 may not be overlapped with the chip bonding pad 3. The redistribution insulating layers RL1 and RL2, the first redistribution patterns RP1, and the first redistribution bonding pads BP1 may constitute a redistribution substrate.

First solder bumps SB1 may be bonded to the first redistribution bonding pads BP1, respectively. The first solder bumps SB1 may be in contact with bottom surfaces and side surfaces of the first redistribution bonding pads BP1 and a bottom surface RL2_B of the second redistribution insulating layer RL2. The first solder bumps SB1 may be formed of, for example, SnAg. The first solder bumps SB1 may be two-dimensionally arranged in a first direction X1 and a second direction X2. In some examples, the first solder bumps SB1 may also cover and/or contact bottom surfaces of the first redistribution bonding pads BP1 and edges of the first redistribution bonding pads BP1. The side surfaces and the bottom surfaces of the first redistribution bonding pads BP1 may meet at the edges of the first redistribution bonding pads.

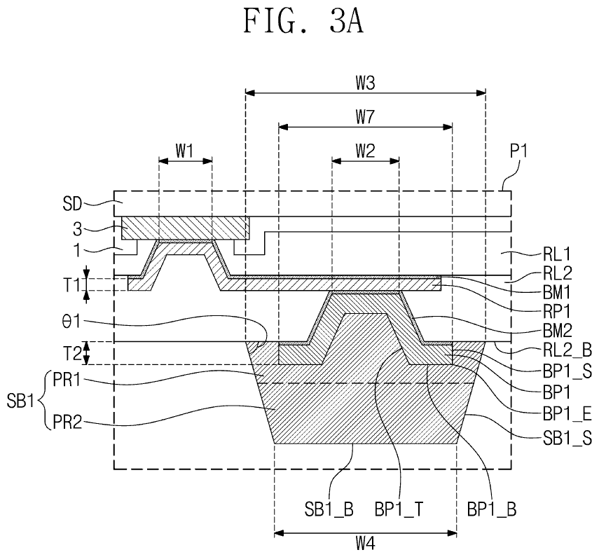

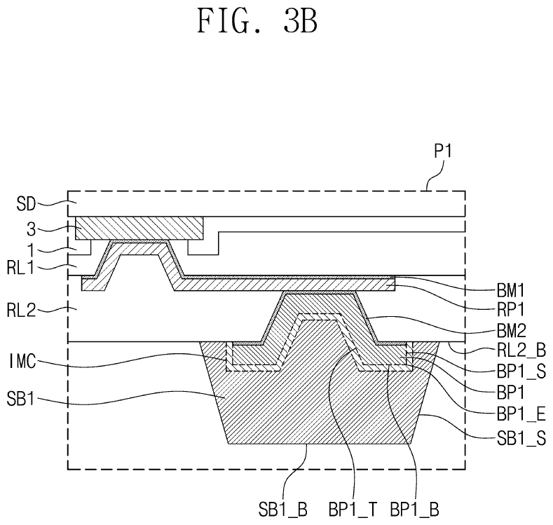

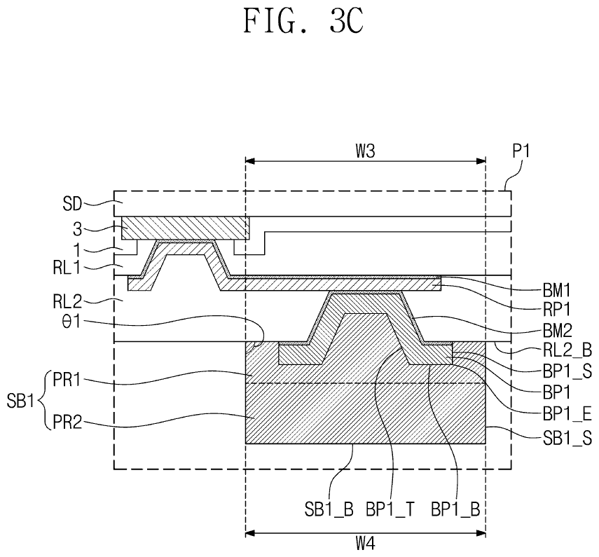

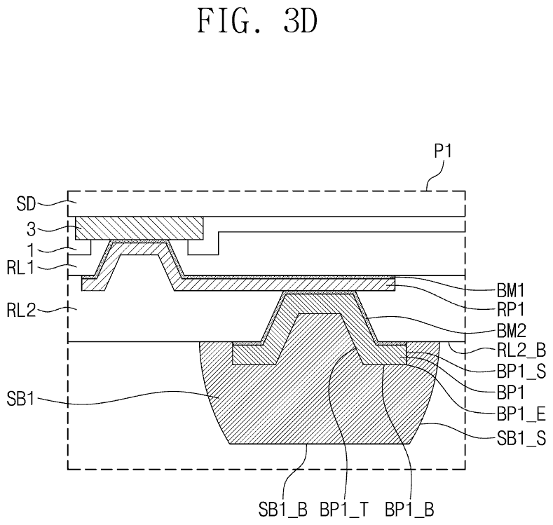

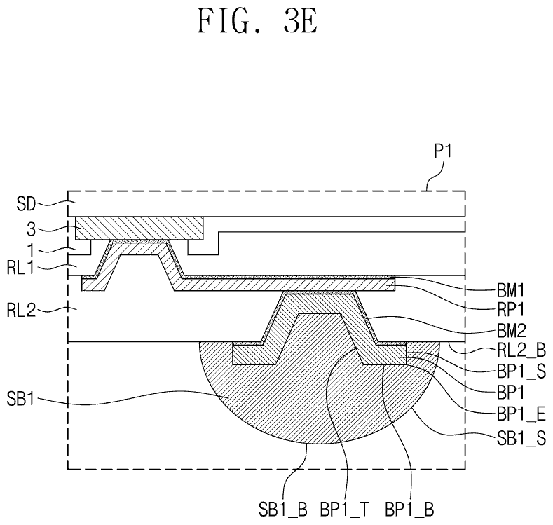

FIGS. 3A to 3E are enlarged sectional views illustrating a portion ‘P1’ of FIG. 1.

Referring to FIG. 3A, a first seed/barrier pattern BM1 may be interposed between the first redistribution pattern RP1 and the first redistribution insulating layer RL1. A second seed/barrier pattern BM2 may be disposed between the first redistribution bonding pad BP1 and the second redistribution insulating layer RL2. Each of the first and second seed/barrier patterns BM1 and BM2 may be formed of or include at least one of titanium, titanium nitride, tantalum, or tantalum nitride.

The first redistribution pattern RP1 may have a first width W1 at a level closest to the chip bonding pad 3. The first redistribution bonding pad BP1 may have a second width W2, which is larger than the first width W1, at a level closest to the first redistribution pattern RP1. The first redistribution pattern RP1 may have a first thickness T1. The first redistribution bonding pad BP1 may have a second thickness T2 different from the first thickness T1. The second thickness T2 may be larger or smaller than the first thickness T1.

A trench BP1_T, which is recessed in an upward direction, may be formed in a bottom surface of the first redistribution bonding pad BP1. The first solder bump SB1 may fill the trench BP1_T. The first solder bump SB1 may cover a side surface BP1_S of the first redistribution bonding pad BP1. The first redistribution bonding pad BP1 may include a material (e.g., copper), which is more easily oxidized or corroded compared with a material of the first solder bump SB1. Since the first solder bump SB1 covers the side surface BP1_S of the first redistribution bonding pad BP1, it may be possible to protect the side surface BP1_S of the first redistribution bonding pad BP1, to prevent the oxidation/corrosion of the material (e.g., copper) of the first redistribution bonding pad BP1, and to minimize and prevent delamination or crack issues in the first redistribution bonding pad BP1. Thus, the reliability of the semiconductor package 100 may be improved.

In some examples, the first solder bumps SB1 may also cover and/or contact bottom surfaces BP1_B of the first redistribution bonding pads BP1 and edges BP1_E of the first redistribution bonding pads BP1. The side surfaces BP1_S and the bottom surfaces BP1_B of the first redistribution bonding pads BP1 may meet at the edges BP1_E of the first redistribution bonding pads.

Referring to FIG. 3A, a width of the first solder bump SB1 may decrease as a distance from the bottom surface RL2_B of the second redistribution insulating layer RL2 increases. For example, the first solder bump SB1 may include a first portion PR1, which is in contact with the bottom surface RL2_B of the second redistribution insulating layer RL2, and a second portion PR2, which is spaced apart from the bottom surface RL2_B of the second redistribution insulating layer RL2. The first portion PR1 and the second portion PR2 may form a single object. The first portion PR1 may have a third width W3. The second portion PR2 may have a fourth width W4 smaller than the third width W3. The largest width of the first redistribution bonding pad BP1 may be a seventh width W7. The largest width of the first solder bump SB1 may be a third width W3. The third width W3 may be larger than the seventh width W7.

Referring to FIG. 3A, the first solder bump SB1 may have a trapezoidal section. An angle between a side surface SB1_S of the first solder bump SB1 and the bottom surface RL2_B of the second redistribution insulating layer RL2 may be a first angle θ1. The first angle θ1 may be smaller than 90°. Accordingly, the first solder bump SB1 may have a tapered shape, for example a width of the first solder bump SB1 in a horizontal direction may decrease as distance from the first redistribution bonding pad BP1 in the vertical direction increases (e.g., the width may decrease towards the bottom of the first solder bump SB1). Alternatively or additionally, this may be referred to as the first solder bump SB1 having a tapered side surface. A bottom surface SB1_B of the first solder bump SB1 may be planarized, e.g., flat in this example. Owing to this shape of the first solder bump SB1, it may be possible to improve the structural stability and to increase an adhesion area and an adhesion strength, in a process of bonding the semiconductor package 100 to another structure (e.g., a package substrate, a module substrate, and so forth).

Referring to FIG. 3B, an inter-metal compound region IMC may be present between the first solder bump SB1 and the first redistribution bonding pad BP1. The inter-metal compound region IMC may be a region, in which the material of the first solder bump SB1 and the material of the first redistribution bonding pad BP1 are mixed, and in which copper, tin, and silver are mixed/bonded. A remaining portion of the semiconductor package may have substantially the same structure as FIG. 3A.

Referring to FIG. 3C, the first solder bump SB1 may have, for example, a rectangular section. A width of the first solder bump SB1 may be constant, regardless of its height. For example, the first portion PR1 of the first solder bump SB1 may have a third width W3, and the second portion PR2 of the first solder bump SB1 may have a fourth width W4 that is equal to the third width W3. A remaining portion of the semiconductor package may have substantially the same structure as FIG. 3A.

Referring to FIG. 3D, a side surface SB1_S of the first solder bump SB1 may have a rounded shape. In this example, the first solder bump SB1 may therefore have a tapered shape, for example a width of the first solder bump SB1 in a horizontal direction may decrease as distance from the first redistribution bonding pad BP1 in the vertical direction increases (e.g., the width may decrease towards the bottom of the first solder bump SB1). Alternatively or additionally, this may be referred to as the first solder bump SB1 having a tapered side surface. A remaining portion of the semiconductor package may have substantially the same structure as FIG. 3A.

Referring to FIG. 3E, the first solder bump SB1 may have a side surface SB1_S and a bottom surface SB1_B that are rounded. The first solder bump SB1 may have a semicircular section. In this example, the first solder bump SB1 may therefore have a tapered shape, for example a width of the first solder bump SB1 in a horizontal direction may decrease as distance from the first redistribution bonding pad BP1 in the vertical direction increases (e.g., the width may decrease towards the bottom of the first solder bump SB1). Alternatively or additionally, this may be referred to as the first solder bump SB1 having a tapered side surface. A remaining portion of the semiconductor package may have substantially the same structure as FIG. 3A. A person of skill in the art will recognize that the shape of the first solder bump SB1 need not be limited to those illustrated in FIGS. 3A to 3E, and may be variously modified in various examples.

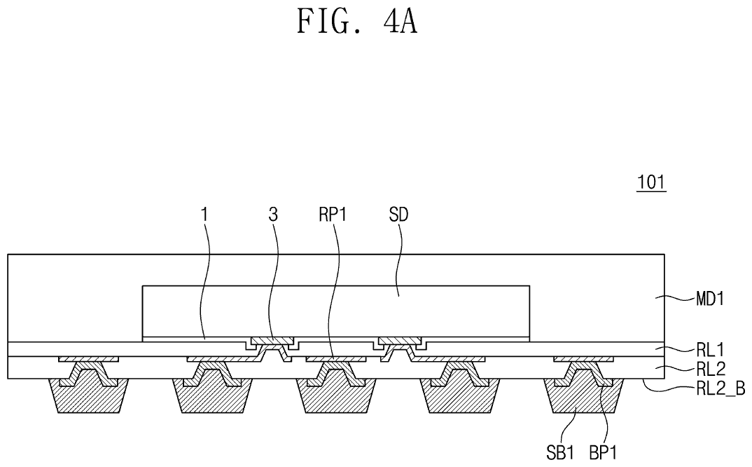

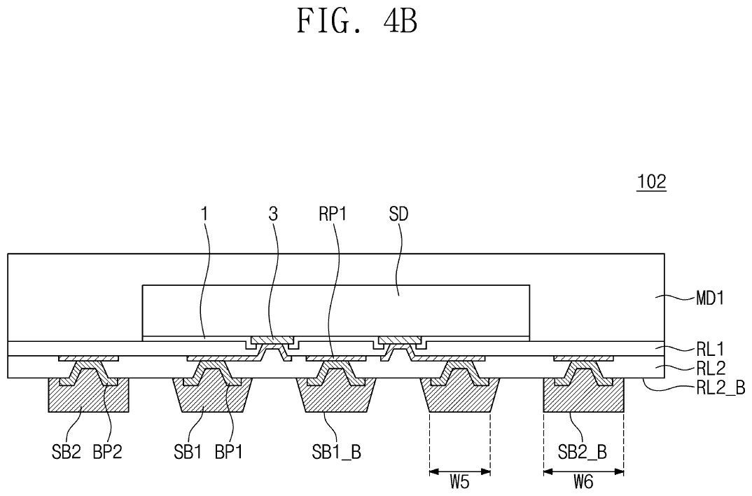

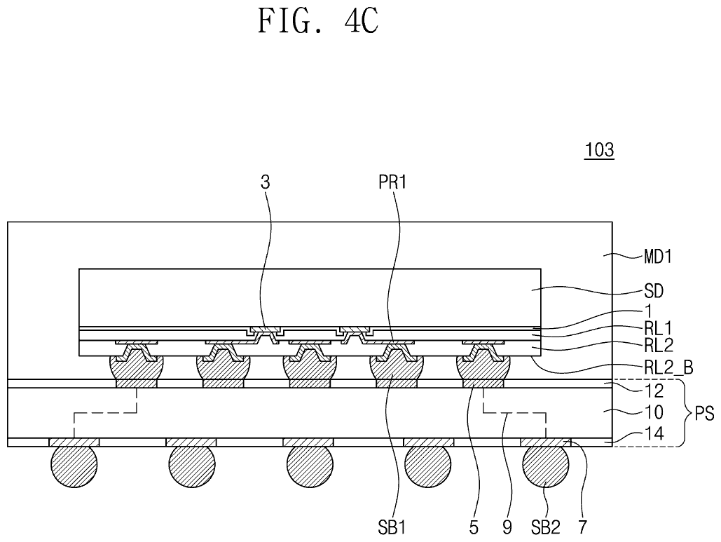

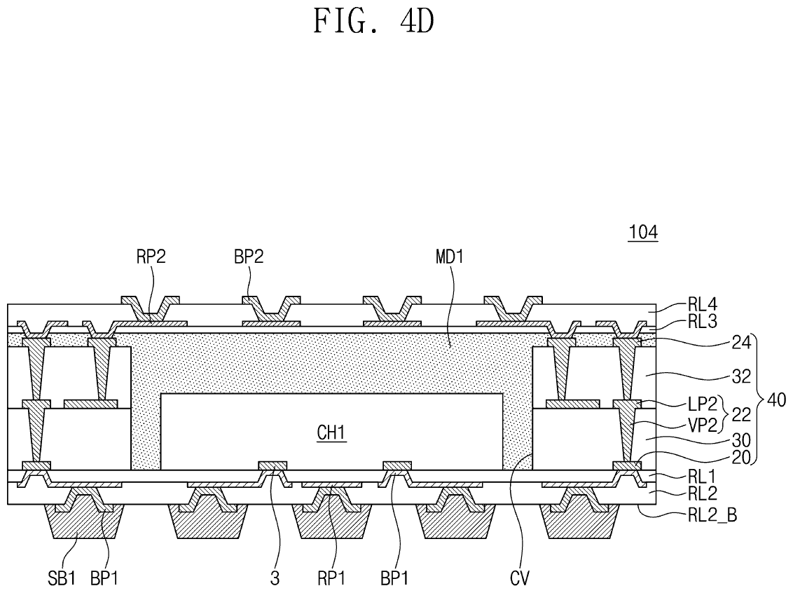

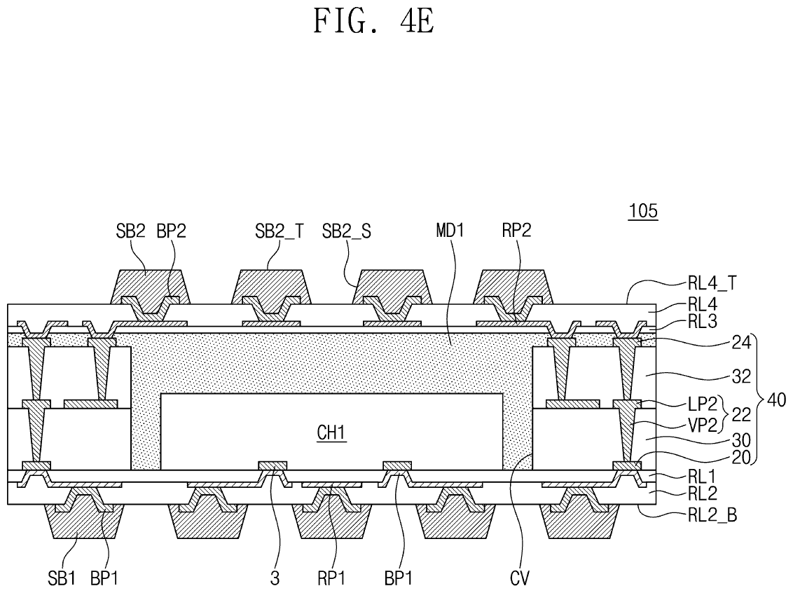

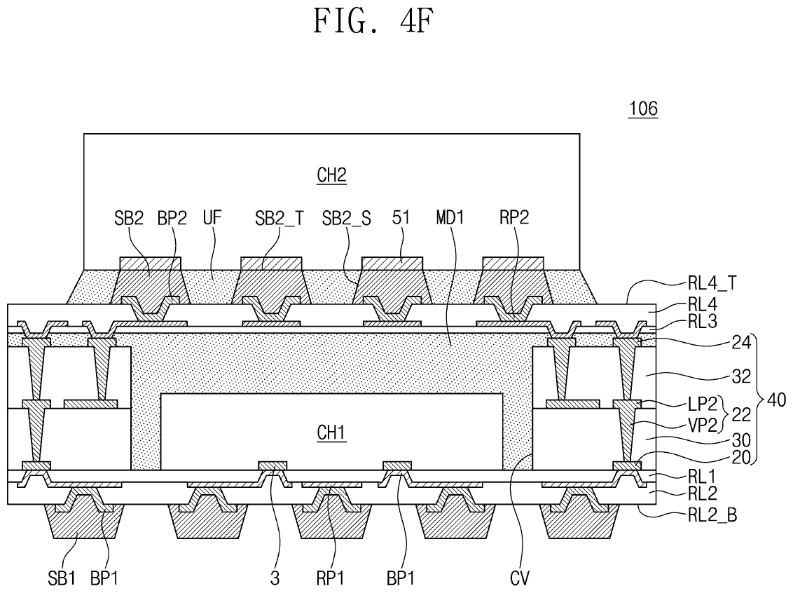

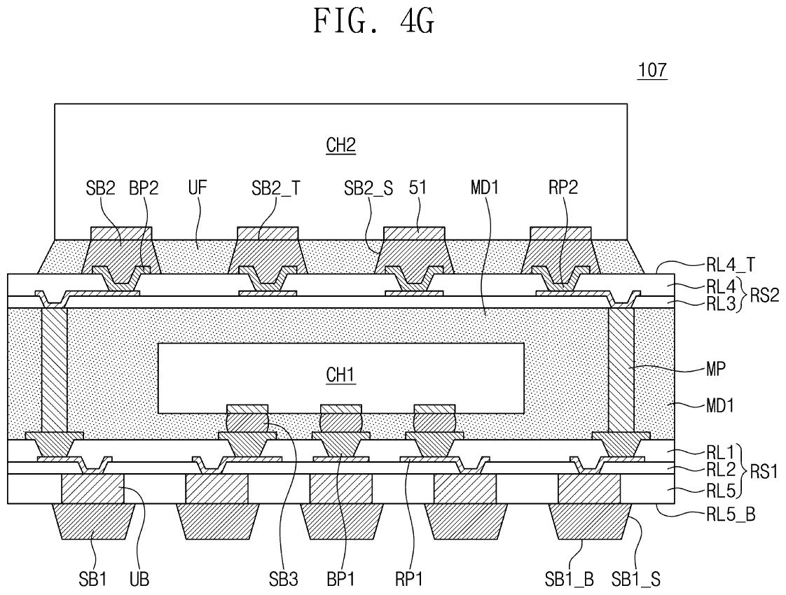

FIG. 4A is a sectional view illustrating a semiconductor package according to an embodiment of the inventive concept.

Referring to FIG. 4A, a semiconductor package 101 in the present embodiment may have a chip-first-type fan-out wafer-level package (FOWLP) structure. Accordingly, in the structure of FIG. 2, the first and second redistribution insulating layers RL1 and RL2 may be laterally extended to a peripheral region that is not overlapped with the semiconductor die SD, when viewed in a plan view. Thus, some of the first redistribution patterns RP1 may be disposed in the peripheral region that is not overlapped with the semiconductor die SD, when viewed in a plan view. The semiconductor package 101 may further include a first mold layer MD1. The first mold layer MD1 may cover side and top surfaces of the semiconductor die SD and a top surface of the first redistribution insulating layer RL1. The first mold layer MD1 may be formed of or include an insulating resin (e.g., epoxy molding compound (EMC)). The first mold layer MD1 may further include fillers, and the fillers may be dispersed in an insulating resin. Some of the first redistribution bonding pads BP1 and some of the first solder bumps SB1 may not be overlapped with the semiconductor die SD. Except for the above features, the semiconductor package 101 may be configured to have substantially the same features as one of the semiconductor packages described with reference to FIGS. 1 to 3E.

FIG. 4B is a sectional view illustrating a semiconductor package according to an embodiment of the inventive concept.

Referring to FIG. 4B, a semiconductor package 102 in the present embodiment may include first redistribution bonding pads BP1 and second redistribution bonding pads BP2, which are spaced apart from each other and are placed at the same level. The first redistribution bonding pads BP1 and the second redistribution bonding pads BP2 may have the same shape. First solder bumps SB1 may be bonded to the first redistribution bonding pads BP1, respectively. Second solder bumps SB2 may be bonded to the second redistribution bonding pads BP2, respectively. The first solder bumps SB1 may cover side surfaces of the first redistribution bonding pads BP1. The second solder bumps SB2 may cover side surfaces of the second redistribution bonding pads BP2.

In some examples, the first solder bumps SB1 may also cover and/or contact bottom surfaces of the first redistribution bonding pads BP1 and edges of the first redistribution bonding pads BP1. The side surfaces and the bottom surfaces of the first redistribution bonding pads BP1 may meet at the edges of the first redistribution bonding pads BP1. Likewise, the second solder bumps SB2 may also cover and/or contact bottom surfaces of the second redistribution bonding pads BP2 and edges of the second redistribution bonding pads BP2. The side surfaces and the bottom surfaces of the second redistribution bonding pads BP2 may meet at the edges of the first redistribution bonding pads BP2.

In this example, the second solder bumps SB2 may have a shape different from a shape of the first solder bumps SB1. For example, the first solder bumps SB1 may have a trapezoidal section. The second solder bumps SB2 may have a rectangular section. A bottom surface SB1_B of the first solder bumps SB1 may have a fifth width W5. A bottom surface SB2_B of the second solder bumps SB2 may have a sixth width W6 different from the fifth width W5. For example, the sixth width W6 may be larger than the fifth width W5.

For example, the second solder bumps SB2 may be disposed to be adjacent to an edge of the semiconductor package 102. The first solder bumps SB1 may be disposed to be adjacent to the center of the semiconductor package 102. Since the sixth width W6 of the second solder bumps SB2 is larger than the fifth width W5 of the first solder bumps SB1, it may be possible to apply a stronger bonding strength to the edge of the semiconductor package 102, when the semiconductor package 102 is bonded to a package substrate or a module substrate. Thus, it may be possible to solve a non-contact issue, which is caused by a loosening phenomenon at the edge of the semiconductor package 102, for example due to insufficient bonding strength between the semiconductor package 102 and a package substrate or module substrate. Moreover, it may be possible to suppress a warpage phenomenon in the semiconductor package 102. Except for the above features, the semiconductor package 102 may be configured to have substantially the same features as one of the semiconductor packages described with reference to FIGS. 1 to 4B.

FIG. 4C is a sectional view illustrating a semiconductor package according to an embodiment of the inventive concept.

Referring to FIG. 4C, a semiconductor package 103 in the present embodiment may further include a package substrate PS, on which a semiconductor die SD is mounted. The package substrate PS may be a double-sided or multi-layered printed circuit board. The package substrate PS may include a substrate body portion 10, a substrate upper insulating layer 12 covering a top surface of the substrate body portion 10, and a substrate lower insulating layer 14 covering a bottom surface of the substrate body portion 10. The substrate body portion 10 may be formed of or include at least one of thermosetting resins (e.g., epoxy resin), thermoplastic resins (e.g., polyimide), composite materials (e.g., prepreg), in which a reinforcement element (e.g., glass fiber and/or inorganic filler) is pre-impregnated with a thermoplastic or thermosetting resin matrix, or photo-curable resins, but the inventive concept is not limited to these examples. At least one of the substrate upper insulating layer 12 and the substrate lower insulating layer 14 may be formed of a photo-solder resist (PSR) layer. The package substrate PS may further include substrate upper pads 5, which are disposed on a top surface of the substrate body portion 10, substrate lower pads 7, which are disposed on a bottom surface of the substrate body portion 10, and substrate internal interconnection lines 9, which connects some of the substrate upper pads 5 to some of the substrate lower pads 7. Each of the substrate upper pads 5, the substrate lower pads 7, and the substrate internal interconnection lines 9 may be formed of or include at least one metallic material (e.g., copper) and/or another conductor.

The semiconductor die SD may be connected to the substrate upper pads 5 using the first solder bumps SB1. The first solder bumps SB1 may cover top surfaces and edges of the substrate upper pads 5. The first solder bumps SB1 may have one of the shapes described with reference to FIGS. 3A to 3D. A side surface of the first solder bumps SB1 may have a linear or rounded shape.

A first mold layer MD1 may cover the semiconductor die SD and a top surface of the package substrate PS and may fill a space between the first solder bumps SB1. Although not shown, the semiconductor package 103 of FIG. 4C may include an under-fill layer that is interposed between the semiconductor die SD and the package substrate PS. In this example, the second solder bumps SB2 may be bonded to the substrate lower pads 7 of the package substrate PS. The shape of the second solder bumps SB2 may be different from the shape of the first solder bumps SB1. For example, the second solder bumps SB2 may have a circular section. Except for the above features, the semiconductor package 103 may be configured to have substantially the same features as one of the semiconductor packages described with reference to FIGS. 1 to 4B.

FIG. 4D is a sectional view illustrating a semiconductor package according to an embodiment of the inventive concept.

Referring to FIG. 4D, a semiconductor package 104 in the present embodiment may be provided to have the structure of FIG. 4A and may further include a connection substrate 40 and third and fourth redistribution insulating layers RL3 and RLA. A first semiconductor chip CH1, the connection substrate 40, and a first mold layer MD1 may be disposed on the top surface of the first redistribution insulating layer RL1. The first semiconductor chip CH1 may be one of various types of memory device chips (e.g., FLASH memory chips, DRAM chips, SRAM chips, EEPROM chips, PRAM chips, MRAM chips, ReRAM chips, high bandwidth memory (HBM) chips, hybrid memory cubic (HMC) chips), microelectromechanical system (MEMS) chips, or application-specific integrated circuit (ASIC) semiconductor chips. In the present disclosure, the semiconductor chip may also be referred to as a ‘semiconductor die’.

The connection substrate 40 may include a cavity region CV, which is formed at a center portion thereof, and the first semiconductor chip CH1 may be disposed in the cavity region CV. The connection substrate 40 may include first and second base layers 30 and 32 and first to third conductive patterns 20, 22, and 24. The first and second base layers 30 and 32 may include an insulating material. For example, the base layers 30 and 32 may be formed of or include at least one of carbon-based materials, ceramic materials, or polymers. Each of the second and third conductive patterns 22 and 24 may include a second via portion VP2 and a second line portion LP2. The first conductive pattern 20 may be disposed in a bottom portion of the first base layer 30. At least one of the first redistribution patterns RP1 may be in contact with the first conductive pattern 20 of the connection substrate 40.

The first mold layer MD1 may cover the connection substrate 40 and the first semiconductor chip CH1 and may fill a space in the connection substrate 40. Third and fourth redistribution insulating layers RL3 and RLA may be sequentially stacked on the first mold layer MD1. Each of the third and fourth redistribution insulating layers RL3 and RLA may be formed of a photoimageable dielectric (PID) layer. Second redistribution patterns RP2 may be disposed between the third and fourth redistribution insulating layers RL3 and RL4. Some of the second redistribution patterns RP2 may penetrate the third redistribution insulating layer RL3 and the first mold layer MD1 and may be in contact with the third conductive patterns 24 of the connection substrate 40. Second redistribution bonding pads BP2 may be disposed on the fourth redistribution insulating layer RL4. The second redistribution bonding pads BP2 may penetrate the fourth redistribution insulating layer RLA and may be in contact with respective ones of the second redistribution patterns RP2.

FIG. 4D illustrates an example, in which two third and fourth redistribution insulating layers RL3 and RLA are provided, but the inventive concept is not limited to this example; for example, three or more redistribution insulating layers may be stacked on a top surface of the first mold layer MD1. In such an example, the fourth redistribution insulating layer RL4 may correspond to the uppermost one of the three or more redistribution insulating layers. Similarly, although FIG. 4D illustrates an example, in which the second redistribution patterns RP2 are provided to form a single layer, the inventive concept is not limited to this example; for example, the second redistribution patterns RP2 may be provided to form two or more layers. Except for the afore-described differences, the semiconductor package 104 may have substantially the same or similar features as those in the previous embodiments.

FIG. 4E is a sectional view illustrating a semiconductor package according to an embodiment of the inventive concept.

Referring to FIG. 4E, a semiconductor package 105 in the present embodiment may be provided to have the structure of FIG. 4D and may further include second solder bumps SB2, which are bonded to the second redistribution bonding pads BP2. The second solder bumps SB2 may cover top surfaces and side surfaces of the second redistribution bonding pads BP2. For example, the second solder bumps SB2 may have an inverted structure of the first solder bumps SB1 of FIGS. 3A to 3E. The number of the second solder bumps SB2 may be different from the number of the first solder bumps SB1. At least one of the second solder bumps SB2 may not be overlapped with the first solder bumps SB1 in a plan view.

In some examples, the second solder bumps SB2 may have an inclined side surface SB2_S and a flat top surface SB2_T. A width of the second solder bump SB2 may decrease with height (e.g., as a vertical level is increased). The side surface SB2_S of the second solder bump SB2 may be inclined at an acute angle with respect to a top surface RL4_T of the fourth redistribution insulating layer RL4. Except for the above features, the semiconductor package 105 may be configured to have substantially the same features as the semiconductor package described with reference to FIG. 4D.

FIG. 4F is a sectional view illustrating a semiconductor package according to an embodiment of the inventive concept.

Referring to FIG. 4F, a semiconductor package 106 in the present embodiment may be provided to have the structure of FIG. 4E but may further include a second semiconductor chip CH2 in contact with the second solder bumps SB2. The second semiconductor chip CH2 may be one of various types of memory device chips (e.g., FLASH memory chips, DRAM chips, SRAM chips, EEPROM chips, PRAM chips, MRAM chips, ReRAM chips, high bandwidth memory (HBM) chips, hybrid memory cubic (HMC) chips), microelectromechanical system (MEMS) chips, or application-specific integrated circuit (ASIC) semiconductor chips. The second semiconductor chip CH2 may include second chip conductive pads 51. The second chip conductive pads 51 may be formed of or include at least one metallic material (e.g., copper). Each of the second chip conductive pads 51 may be in contact with the top surface SB2_T of the second solder bump SB2. The second solder bumps SB2 may be in contact with a side surface and/or an edge of the second chip conductive pad 51. As in the example of FIG. 4E, the second solder bumps SB2 may have an inclined side surface SB2_S and a flat top surface SB2_T. Thus, owing to the shape of the second solder bumps SB2, it may be possible to improve the structural stability in a process of mounting the second semiconductor chip CH2 on the second solder bumps SB2. In addition, as second solder bumps SB2 may cover a side surface and/or edge of the second chip conductive pad 51, it may be possible to prevent a delamination or crack issue in the side surface and/or edge of the second chip conductive pad 51.

FIG. 4G is a sectional view illustrating a semiconductor package according to an embodiment of the inventive concept.

Referring to FIG. 4G, a semiconductor package 107 in the present embodiment may be provided to have a chip-last-type fan-out wafer-level package (FOWLP) structure. The semiconductor package 107 may include a first redistribution substrate RS1, a first semiconductor chip CH1, a first mold layer MD1, a second redistribution substrate RS2, and a second semiconductor chip CH2. The first redistribution substrate RS1 may include fifth, second, and first redistribution insulating layers RL5, RL2, and RL1 sequentially stacked. Each of the fifth, second and first redistribution insulating layers RL5, RL2, and RL1 may be formed of a photoimageable dielectric (PID) layer. A lower conductive bump UB may be disposed in the fifth redistribution insulating layer RL5. The lower conductive bump UB may include, for example, copper. A bottom surface of the lower conductive bump UB may be coplanar with a bottom surface RL5_B of the fifth redistribution insulating layer RL5.

A first solder bump SB1 may be bonded to the lower conductive bump UB. The first solder bump SB1 may have a trapezoidal, rectangular, or semicircular section, as described with reference to FIGS. 3A to 3E. The first solder bump SB1 may cover a bottom surface, a side surface, and/or an edge (e.g., where the bottom and side surfaces meet) of the lower conductive bump UB and the bottom surface RL5_B of the fifth redistribution insulating layer RL5. First redistribution patterns RP1 may be disposed between the first and second redistribution insulating layers RL1 and RL2. At least one of the first redistribution patterns RP1 may penetrate the second redistribution insulating layer RL2 and may be in contact with a top surface of the lower conductive bump UB. A first redistribution bonding pad BP1 may be placed on a top surface of the first redistribution insulating layer RL1. The first redistribution bonding pad BP1 may penetrate the first redistribution insulating layer RL1 and may be in contact with one of the first redistribution patterns RP1. The first redistribution bonding pad BP1 may have a flat top surface. The first redistribution bonding pad BP1 may have a ‘T’-shaped section.

A first semiconductor chip CH1 may be mounted on the first redistribution substrate RS1 using third solder bumps SB3 interposed therebetween. The third solder bump SB3 may have a rounded side surface. The third solder bump SB3 may be in contact with the top surface of the first redistribution bonding pad BP1 and may expose a side surface and/or an edge of the first redistribution bonding pad BP1. A conductive pillar MP may be disposed on an edge of the first redistribution substrate RS1. In an embodiment, the conductive pillar MP may be formed of or include at least one metallic material (e.g., copper). The first semiconductor chip CH1 and the first redistribution substrate RS1 may be covered with a first mold layer MD1. The first mold layer MD1 may fill a space between the third solder bumps SB3. The conductive pillar MP may penetrate the first mold layer MD1.

The second redistribution substrate RS2 may be disposed on the first mold layer MD1. The second redistribution substrate RS2 may include third and fourth redistribution insulating layers RL3 and RL4, second redistribution patterns RP2, and second redistribution bonding pads BP2, which are sequentially stacked. Except for the above features, the semiconductor package 107 may be configured to have substantially the same features as the semiconductor package described with reference to FIG. 4F.

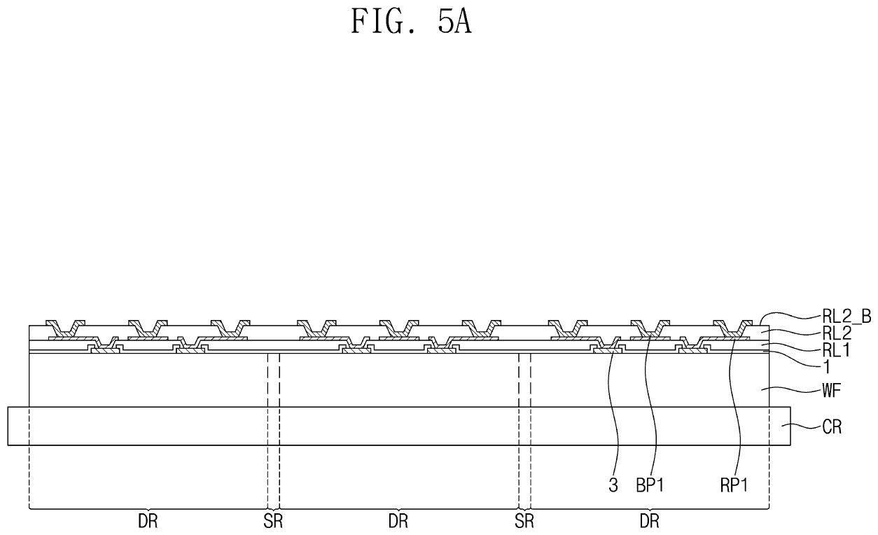

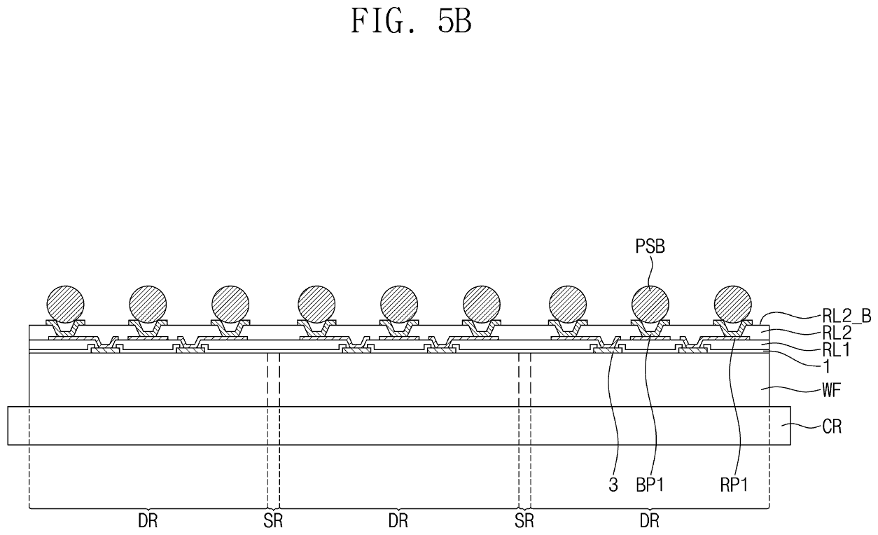

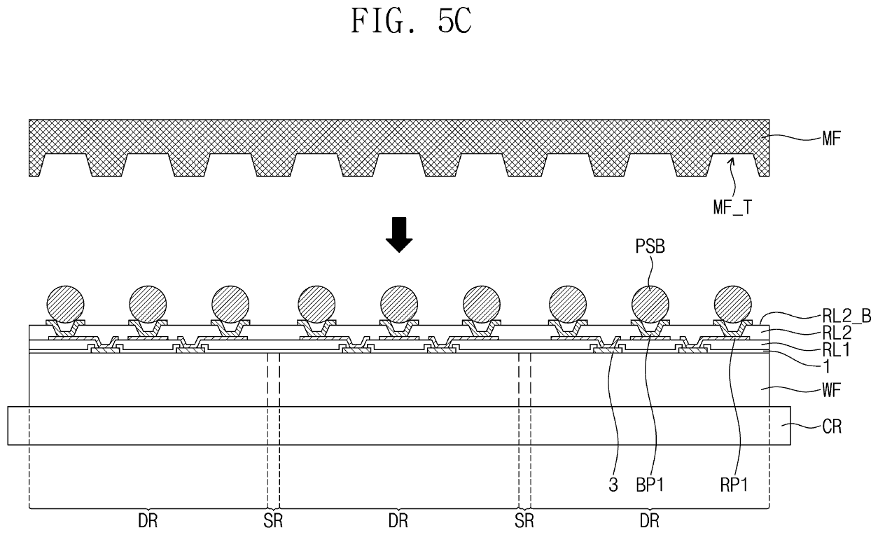

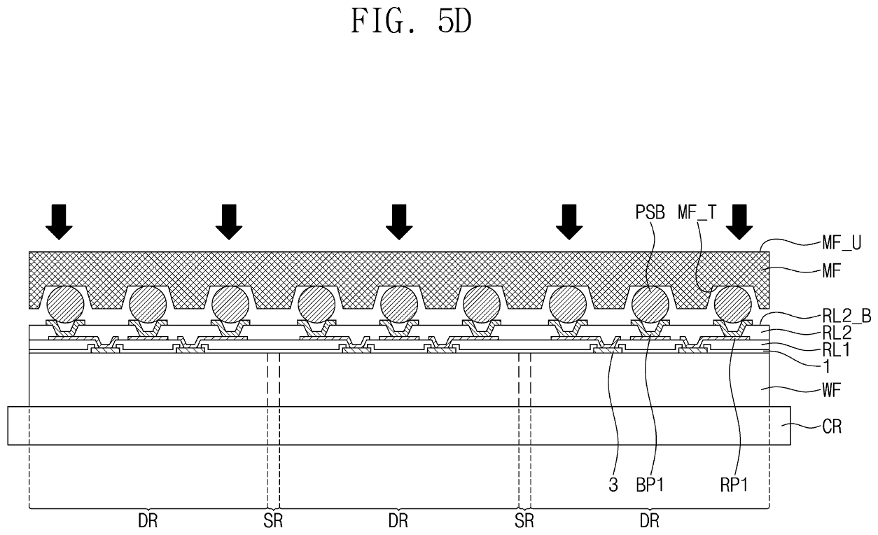

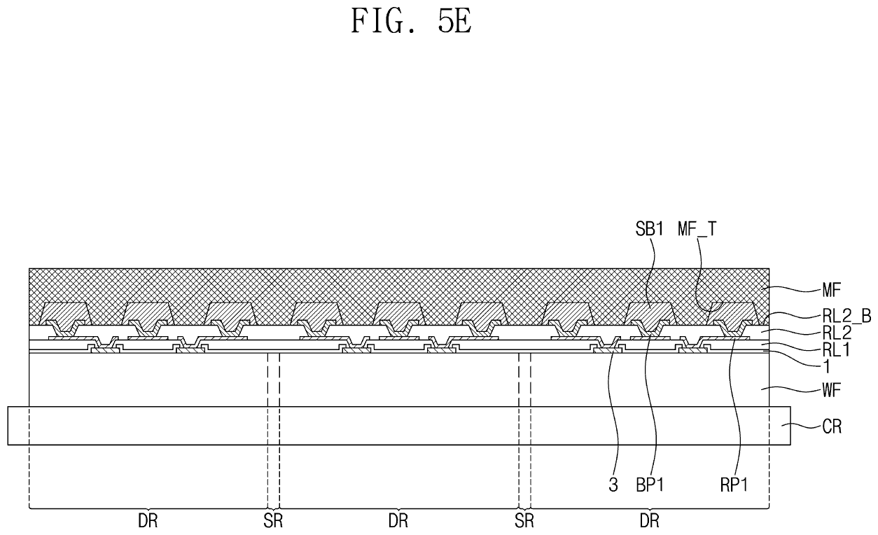

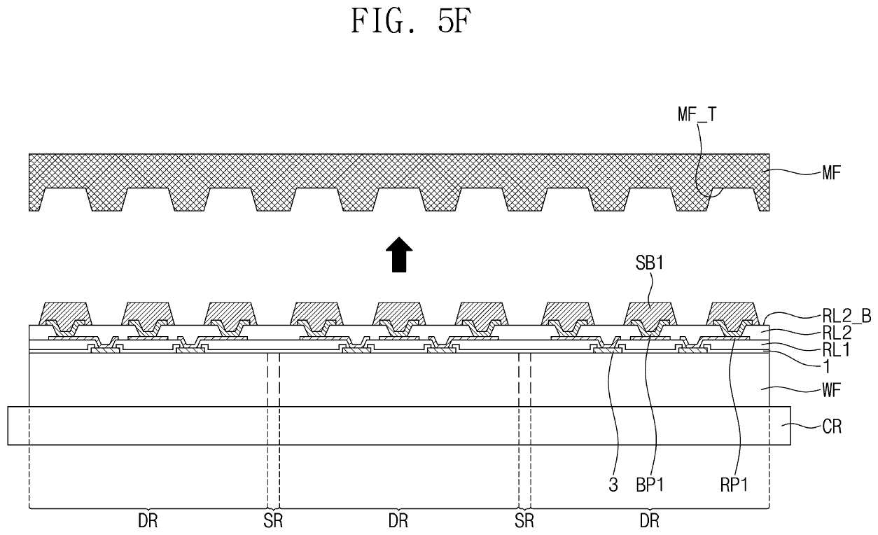

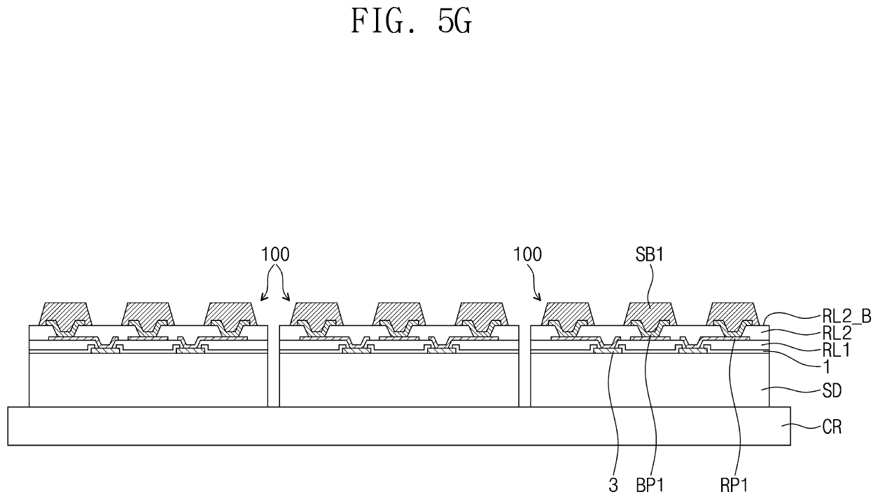

FIGS. 5A to 5G are sectional views sequentially illustrating a process of fabricating the semiconductor package of FIG. 2, according to an embodiment of the inventive concept.

Referring to FIG. 5A, a device substrate WF may be bonded to a carrier substrate CR using an adhesive layer (not shown) interposed therebetween. The device substrate WF may include device regions DR and a separation region SR therebetween. A chip protection layer 1 and first and second redistribution insulating layers RL1 and RL2 may be sequentially stacked on the device substrate WF. Chip bonding pads 3, first redistribution patterns RP1, and first redistribution bonding pads BP1 may be disposed on the device region DR of the device substrate WF.

Referring to FIG. 5B, solder balls PSB may be placed on the device substrate WF. The solder balls PSB may have a spherical shape and may be in contact with top surfaces of the first redistribution bonding pads BP1. In this step, the solder balls PSB may not fill the trench BP1_T (e.g., see FIG. 3A) of the first redistribution bonding pads BP1.

Referring to FIGS. 5C and 5D, a mold frame MF may be placed on the device substrate WF and the solder balls PSB. The mold frame MF may be formed of or include at least one of silicon, glass, ceramic, or metallic materials. Mold trenches MF_T, which correspond to the solder balls PSB, may be formed in a bottom surface of the mold frame MF. The mold frame MF may be placed such that the solder balls PSB are inserted into the mold trenches MF_T, respectively. Here, the lowermost portion of the mold frame MF may not be in contact with a top surface RL2_B of the second redistribution insulating layer RL2. A width of each of the mold trenches MF_T may be larger than the largest width of each of the first redistribution bonding pads BP1.

Referring to FIGS. 5D and 5E, a reflow process of applying heat and pressure to a top surface of the mold frame MF may be performed to melt the solder balls PSB. Thus, the lowermost portion of the mold frame MF may be in contact with the top surface RL2_B of the second redistribution insulating layer RL2, and the melted solder balls PSB may fill the mold trenches MF_T, respectively. When the mold frame MF is cooled, the melted solder balls PSB may be solidified to form the first solder bumps SB1. The first solder bumps SB1 may have the shape that is defined by the mold trenches MF_T. By variously modifying the shape of the mold trenches MF_T, the first solder bumps SB1 may have one of the shapes described with reference to FIGS. 3A to 3E and FIG. 4B, or any other shape.

Referring to FIG. 5F, the mold frame MF may be detached from the top surface RL2_B of the second redistribution insulating layer RL2. Thus, surfaces of the first solder bumps SB1 may be exposed.

Referring to FIGS. 5F and 5G, a singulation process, such as a dicing or sawing process, may be performed to remove the separation region SR of the device substrate WF and to form the semiconductor packages 100 including the semiconductor dies SD. Next, the semiconductor packages 100 may be detached from the carrier substrate CR. As a result, the semiconductor package 100 may be fabricated to have the structure of FIG. 2.

In the semiconductor package according to an embodiment of the inventive concept, it may be possible to efficiently form a solder bump of a stable structure, to prevent a process failure, such as copper corrosion, and to increase a yield in a fabrication process.

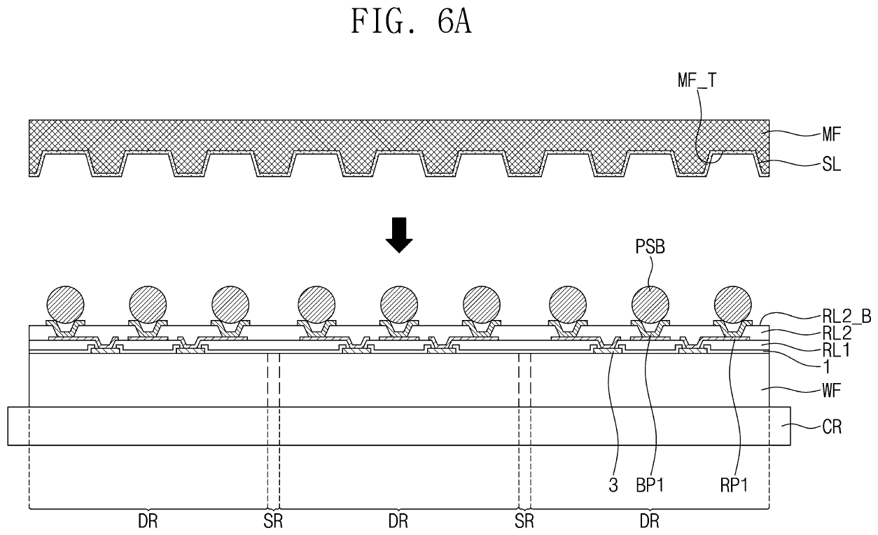

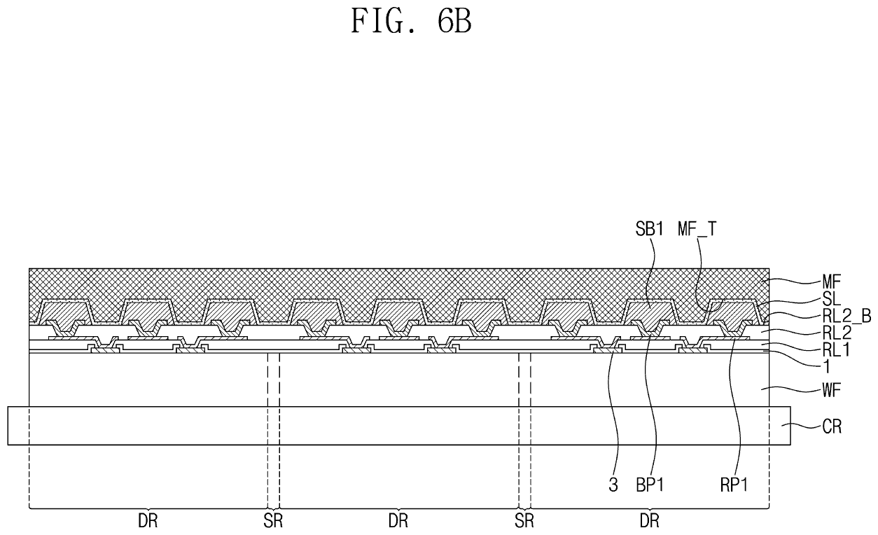

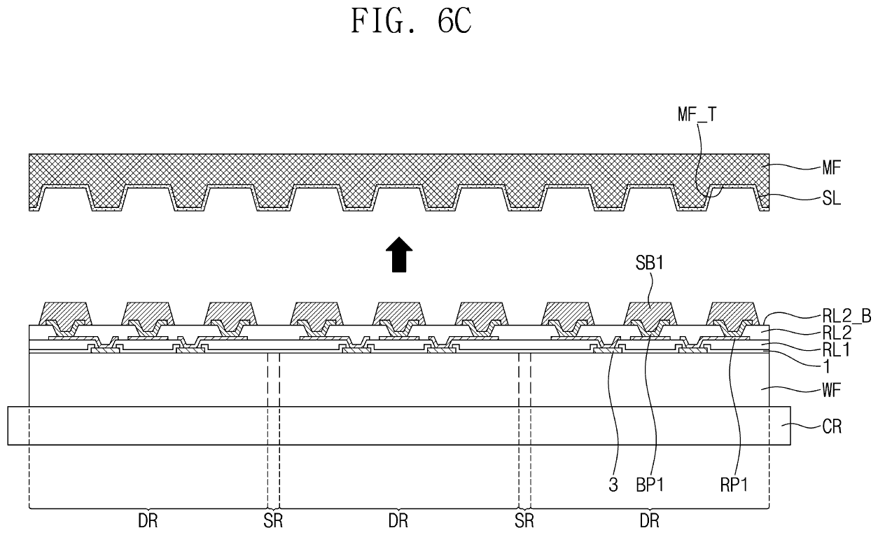

FIGS. 6A to 6C are sectional views sequentially illustrating a process of fabricating the semiconductor package of FIG. 2, according to an embodiment of the inventive concept.

Referring to FIG. 6A, in a method of fabricating a semiconductor package according to an embodiment of the inventive concept, a separation layer SL may be attached to a bottom surface of the mold frame MF. The separation layer SL may be an adhesive layer or a resin layer, which is cured or decomposed by heat or light. The separation layer SL may be conformally formed along an uneven profile of the bottom surface of the mold frame MF.

Referring to FIGS. 6A and 6B, solder balls PSB may be placed on the device substrate WF. The solder balls PSB may have a spherical shape and may be in contact with top surfaces of the first redistribution bonding pads BP1. In this step, the solder balls PSB may not fill the trench BP1_T of the first redistribution bonding pads BP1 (e.g., see FIG. 6A). A mold frame MF may be placed on the device substrate WF and the solder balls PSB. The solder balls PSB may be melted by applying heat and pressure to a top surface of the mold frame MF. Thus, the lowermost portion of the mold frame MF may be in contact with the top surface RL2_B of the second redistribution insulating layer RL2, and the melted solder balls PSB may fill the mold trenches MF_T, respectively. Here, the melted solder balls PSB may be in contact with the separation layer SL. When the mold frame MF is cooled, the melted solder balls PSB may be solidified to form the first solder bumps SB1.

Referring to FIG. 6C, the mold frame MF may be detached from a top surface RL2_B of the second redistribution insulating layer RL2. Here, the separation layer SL may be decomposed by applying heat or light to the separation layer SL. Thus, the mold frame MF may be easily detached from surfaces of the first solder bumps SB1. Next, a singulation process, such as a dicing or sawing process, may be performed to remove the separation region SR of the device substrate WF and to form the semiconductor packages 100 including the semiconductor dies SD.

In a semiconductor package according to an embodiment of the inventive concept, a solder bump may be provided to cover a side surface and/or an edge of a bonding pad, and thus, it may be possible to reduce or prevent a delamination or crack issue in the bonding pad. Accordingly, the reliability of the semiconductor package may be improved. In a method of fabricating a semiconductor package according to an embodiment of the inventive concept, a mold frame may be used to efficiently form the solder bump of a stable structure. Accordingly, a process failure may be reduced, and a production yield may be increased.

While example embodiments of the inventive concept have been particularly shown and described, it will be understood by one of ordinary skill in the art that variations in form and detail may be made therein without departing from the spirit and scope of the attached claims. The embodiments of FIGS. 1 to 6C may be combined to realize aspects of the inventive concept.

1. A semiconductor package, comprising:
a semiconductor die;
first and second redistribution insulating layers sequentially stacked below the semiconductor die;
first redistribution bonding pads disposed on a bottom surface of the second redistribution insulating layer; and
first solder bumps bonded to the first redistribution bonding pads,
wherein the first solder bumps cover and contact side surfaces of the first redistribution bonding pads.

2. The semiconductor package of claim 1, wherein the first solder bumps extend to be in contact with the bottom surface of the second redistribution insulating layer.

3. The semiconductor package of claim 1, wherein each of the first solder bumps has a side surface that is inclined at an acute angle with respect to the bottom surface of the second redistribution insulating layer.

4. The semiconductor package of claim 1, wherein each of the first solder bumps comprises a first portion, which is in contact with the bottom surface of the second redistribution insulating layer, and a second portion, which is spaced apart from the bottom surface of the second redistribution insulating layer,
the first portion has a first width, and
the second portion has a second width smaller than the first width.

5. The semiconductor package of claim 1, wherein each of the first redistribution bonding pads has a trench formed in a bottom surface thereof, and
each of the first solder bumps fills the trench of a corresponding one of the first redistribution bonding pads.

6. The semiconductor package of claim 1, wherein each of the first solder bumps has a trapezoidal, rectangular, or semicircular section.

7. The semiconductor package of claim 1, wherein each of the first solder bumps has a flat bottom surface.

8. The semiconductor package of claim 1, further comprising a redistribution pattern, which is interposed between the first and second redistribution insulating layers and is in contact with one of the first redistribution bonding pads,
wherein the redistribution pattern has a first thickness, and
the one of the first redistribution bonding pads has a second thickness different from the first thickness.

9. The semiconductor package of claim 1, further comprising a mold layer covering a side surface of the semiconductor die and the first redistribution insulating layer,
wherein at least one of the first solder bumps overlaps the mold layer.

10. The semiconductor package of claim 9, further comprising:
third and fourth redistribution insulating layers sequentially stacked on the mold layer;
second redistribution bonding pads disposed on the fourth redistribution insulating layer; and
second solder bumps bonded to the second redistribution bonding pads, respectively,
wherein the second solder bumps cover and contact side surfaces of the second redistribution bonding pads.

11. The semiconductor package of claim 1, further comprising a package substrate, on which the semiconductor die is mounted,
wherein the package substrate comprises substrate upper pads, and
wherein the first solder bumps are in contact with upper edges of the substrate upper pads, respectively.

12. The semiconductor package of claim 1, further comprising inter-metal compound regions, which are respectively interposed between the first redistribution bonding pads and the first solder bumps.

13. A semiconductor package, comprising:
a semiconductor die;
a chip bonding pad disposed on a bottom surface of the semiconductor die;
first and second redistribution insulating layers stacked below the semiconductor die;
a first redistribution pattern, which penetrates the first redistribution insulating layer and is connected to the chip bonding pad;
a first redistribution bonding pad, which penetrates the second redistribution insulating layer and is connected to the first redistribution pattern; and
a first solder bump bonded to the first redistribution bonding pad,
wherein:
a bottom surface of the first solder bump is flat,
the first solder bump is in contact with a bottom surface of the second redistribution insulating layer,
the first redistribution bonding pad does not overlap the chip bonding pad in a vertical direction,
the first redistribution pattern has a first thickness, and
the first redistribution bonding pad has a second thickness different from the first thickness.

14. The semiconductor package of claim 13, further comprising:
a second redistribution pattern interposed between the first and second redistribution insulating layers;
a second redistribution bonding pad, which penetrates the second redistribution insulating layer and is connected to the second redistribution pattern; and
a second solder bump bonded to the second redistribution bonding pad,
wherein the second solder bump has a shape different from a shape of the first solder bump.

15. The semiconductor package of claim 14, wherein:
a lower portion of the first solder bump has a first width, and
a lower portion of the second solder bump has a second width different from the first width.

16. The semiconductor package of claim 13, wherein the first solder bump comprises a first portion, which is in contact with the bottom surface of the second redistribution insulating layer, and a second portion, which is spaced apart from the bottom surface of the second redistribution insulating layer,
the first portion has a first width, and
the second portion has a second width smaller than the first width.

17. The semiconductor package of claim 13, wherein the first solder bump has a side surface that is inclined at an acute angle with respect to the bottom surface of the second redistribution insulating layer.

18. A semiconductor package, comprising:
a semiconductor die;
first and second redistribution insulating layers sequentially stacked below the semiconductor die;
a first redistribution bonding pad and a second redistribution bonding pad disposed below a bottom surface of the second redistribution insulating layer;
a first solder bump bonded to the first redistribution bonding pad, and having a tapered shape that decreases in width from a height where the first solder bump contacts a side surface of the first redistribution bonding pad and in a downward direction away from the bottom surface of the second redistribution insulating layer; and
a second solder bump bonded to the second redistribution bonding pad, and having a tapered shape that decreases in width from a height where the second solder bump contacts a side surface of the second redistribution bonding pad and in the downward direction,
wherein a bottom portion of the first solder bump has a first horizontal width, and
wherein a bottom portion of the second solder bump has a second horizontal width different from the first horizontal width.

19. The semiconductor package of claim 18, wherein the second solder bump has a shape different from a shape of the first solder bump.

20. The semiconductor package of claim 18, wherein the first solder bump comprises a first portion, which is in contact with the bottom surface of the second redistribution insulating layer, and a second portion, which is spaced apart from the bottom surface of the second redistribution insulating layer and includes a bottom surface of the first solder bump,
the first portion has a third horizontal width, and
the second portion has a fourth horizontal width smaller than the third horizontal width.

21-29. (canceled)
